(19) United States
(12) Patent Application Publication
(10) Pub. No.: US 2021/0185850 A1
(43) Pub. Date: Jun. 17, 2021

(54) HYBRID LIQUID COOLING

(71) Applicant: Intel Corporation, Santa Clara, CA (US)

(72) Inventors: Devdatta Prakash Kulkarni, Portland, OR (US); Nishi Ahuja, Portland, OR (US); Sandeep Ahuja, Portland, OR (US); Timothy M. Gates, Hillsboro, OR (US); Casey Robert Winkel, Hillsboro, OR (US)

(73) Assignee: Intel Corporation, Santa Clara, CA (US)

(21) Appl. No.: 17/185,681

(22) Filed: Feb. 25, 2021

(51) Int. Cl. H05K 7/20

(52) U.S. Cl. CPC H05K 7/203; H05K 7/20381; H05K 7/20318; H05K 7/20327

(57) ABSTRACT

Two liquid cooling mechanisms are provided for cooling integrated circuit components immersed in an open bath immersion tank. In the first mechanism, heat generated by high-thermal design power (TDP) components is absorbed by a working fluid passing through cold plates coupled to the high-TDP components. The cold plates are part of direct liquid cooling loops attached to supply and return manifolds fluidly connected to a cooling distribution unit. In the second mechanism, integrated circuit components not coupled to any of the direct liquid cooling loops dissipate heat directly to the immersion fluid. In some embodiments, the tank is a closed bath immersion tank and heat captured by the working fluid is reclaimed and converted to electricity. Working fluid flow rate can be adjusted based on integrated circuit component power consumption levels to achieve a desired working fluid temperature as it enters an energy reclamation unit.

### BACKGROUND

In immersion bath-based liquid cooling systems, integrated circuit components are immersed in an immersion tank filled with a dielectric immersion fluid. The integrated circuit components are cooled by the heat generated by the components dissipating into the immersion fluid. Two types of immersion tanks can be used in liquid immersion cooling systems—open bath and closed bath. In open bath systems, the immersion tank can be covered or uncovered and operates at atmospheric pressure. In closed bath systems, the immersion tank is sealed and the immersion fluid is thus sealed off from the environment. A heat exchanger cools the immersion fluid.

In direct liquid cooling systems, an integrated circuit component is cooled by a working fluid that flows through a cold plate coupled to the integrated circuit component. A pump circulates the working fluid through a direct liquid cooling loop comprising the cold plate. Working fluid heated by the integrated circuit component is cooled by a heat exchanger.

### BRIEF DESCRIPTION OF THE DRAWINGS

FIG. 1 is a table comparing characteristics of various liquid cooling solutions.

FIG. 2A illustrates a hybrid cooling system to cool a plurality of system boards located within an open bath immersion tank.

FIG. 2B illustrates a front view of one of the system boards of FIG. 2A.

FIG. 3 is an example hybrid liquid cooling system comprising an energy reclamation unit.

FIG. 4 is a flowchart of an example hybrid liquid cooling method.

FIG. 5 is a block diagram of an example computing system that can be cooled by a hybrid liquid cooling system or that can provide working fluid flow rate control or gas pressure control in a hybrid liquid computing system.

FIG. 6 is a block diagram of an exemplary processor unit that can execute instructions as part of implementing technologies described herein.

### DETAILED DESCRIPTION

The power consumption of various types of processor units (such as XPUs (e.g., central processing units (CPUs), graphics processing units (GPUs)), add-in cards, and memories are increasing generation-over-generation. Liquid immersion cooling is becoming an attractive option for the cooling of high-performance computing systems, such as data center servers, due to its high heat capture rate, and enablement of low power usage effectiveness (PUE), high component reliability in corrosive atmospheric conditions, and modular and scalable designs. The emergence of edge computing and 5G cellular network technologies is further accelerating the adoption of liquid immersion cooling.

Liquid immersion cooling (or immersion cooling) can be divided into two general approaches—single-phase and two-phase immersion cooling. In both approaches, integrated circuit components are immersed in an immersion fluid that is in a liquid state before the immersion fluid is heated by the immersed components. In single-phase immersion cooling, the immersion fluid remains in its liquid state as it is heated under expected operating conditions. In two-phase immersion cooling, a portion of the immersion fluid undergoes a phase change from liquid to gas as the immersion fluid is heated under expected operating conditions. A single-phase immersion cooling implementation can utilize an open bath immersion tank or a closed bath immersion tank and a two-phase immersion cooling implementation utilizes a closed bath immersion tank.

As used herein, the phrases “single-phase immersion fluid” and “single-phase working fluid” refer to immersion fluids and working fluids, respectively, that remain in their liquid state as they are heated under expected operating conditions. As used herein, the phrases “two-phase immersion fluid” and “two-phase working fluid” refer to immersion fluids and working fluids, respectively, a portion of which is expected to undergo a phase change from liquid to gas under expected operating conditions.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the instructions contained in the software or firmware are not actively being executed by the system, device, platform, or resource.

As used herein, the term “integrated circuit component” refers to a packaged or unpacked integrated circuit product. A packaged integrated circuit component comprises one or more integrated circuits mounted on a package substrate. In one example, a packaged integrated circuit component contains one or more processor units mounted on a substrate, an exterior side of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein, such as a processor unit (e.g., system-on-a-chip (SoC), processor cores, graphics processor unit (GPU), accelerator), I/O controller, chipset processor, memory, or network interface controller.

While two-phase immersion cooling provides good cooling performance, the high cost of two-phase immersion fluid and costs associated with losing immersion fluid during operation due to vapor loss has limited its adoption. While single-phase immersion cooling can avoid the loss of immersion fluid over time, its cooling capabilities are generally less than that of two-phase immersion cooling due to single-phase immersion fluid having a lower specific heat, higher density, and higher viscosity.

Two parameters of immersion fluids that can be considered when choosing which immersion fluid to use in an immersion cooling implementation are its flammability and global warming potential (GWP) number, with a lower GWP number indicating that a material contributes less to global warming. Some synthetic single-phase immersion fluids (e.g., Novec fluids) have good thermal performance but also have a high GWPs. As there are worldwide efforts to phase out the use of greenhouse gases, such as hydrofluorocarbons, there is interest in using non-GWP or low-GWP materials (e.g., materials having a GWP<1) where possible. The hybrid liquid cooling technologies disclosed herein can provide for the liquid cooling of racks comprising high-performance integrated circuit components using non-flammable and/or non-GWP or low-GWP fluids. The use of such technologies can aid large cloud service providers (CSPs), high-performance computing (HPC) system vendors, and other entities that may begin to increasingly rely on immersion cooling in their data centers to meet their declared environmental sustainability (e.g., carbon-neutral, carbon-negative) goals.

Various liquid immersion cooling approaches exist, but they may suffer from various disadvantages. In a first existing approach, a single-phase immersion fluid is used to cool integrated circuit components immersed in an open bath immersion tank. Air-cooled heat sinks attached to the integrated circuit components can aid in dissipating heat generated by the integrated circuit components to the immersion fluid, which is a synthetic oil, but such systems may not be able to adequately remove the high amount of heat generated by high-thermal design power (TDP) integrated circuit components due to the limited thermal performance of synthetic oils.

In a second existing approach, a single-phase immersion fluid is used in a closed chassis computing system. The single-phase immersion fluid, which is mineral oil or synthetic oil, flows into cold plates coupled to integrated circuit components and overflows or spills off the cold plates (e.g., open pin fin cold plates) to provide cooling for other integrated circuit components on a system board. Disadvantages of this second approach may include the use of low thermal performance immersion fluids (mineral oils or synthetic oil), the need for a closed chassis to prevent the immersion fluid from leaking outside the chassis, the need for a rack to possess sufficient mechanical strength to support the additional weight of fluid-filled computing systems, and the serviceability and replacement limitations presented by closed chassis computing systems.

In a third existing approach, a single-phase immersion fluid in a closed-chassis computing system cools integrated circuit components with a separate direct liquid cooling loop cooling high-TDP integrated circuit components. The closed-chassis system comprises dedicated pumps and a dedicated heat exchanger to circulate and cool the immersion fluid and the direct liquid cooling loop working fluid. The direct liquid cooling loop working fluid can be a single-phase working fluid, such as water. Disadvantages of this third solution may include the disadvantages of the second existing solution plus the added cost associated with having dedicated pumps and a dedicated heat exchanger for the individual chassis (e.g., cost of pumps and heat exchanger, cost of a sturdier rack to support the additional pump and heat exchanger weight).

In a fourth existing approach, a two-phase immersion fluid is used in a closed bath immersion tank. Disadvantages of this fourth approach may include the possible use of high-GWP immersion fluids; the need for a sealed chassis, immersion tank, or rack to prevent immersion fluid vapor leaks; regulatory approval and the added cost of fire suppression capabilities if a flammable two-phase immersion fluid is used; serviceability and replacement challenges due to the potential loss of immersion fluid while removing or inserting a rack-level computing system (e.g., blade, server, sled); and the high cost of two-phase immersion fluids. The high cost of two-phase immersion fluids may require high-density deployments, which may not broadly support standard original equipment manufacturer (OEM) server designs and could limit the use of two-phase immersion cooling solutions to only the largest CSPs or other entities that build data centers at scale.

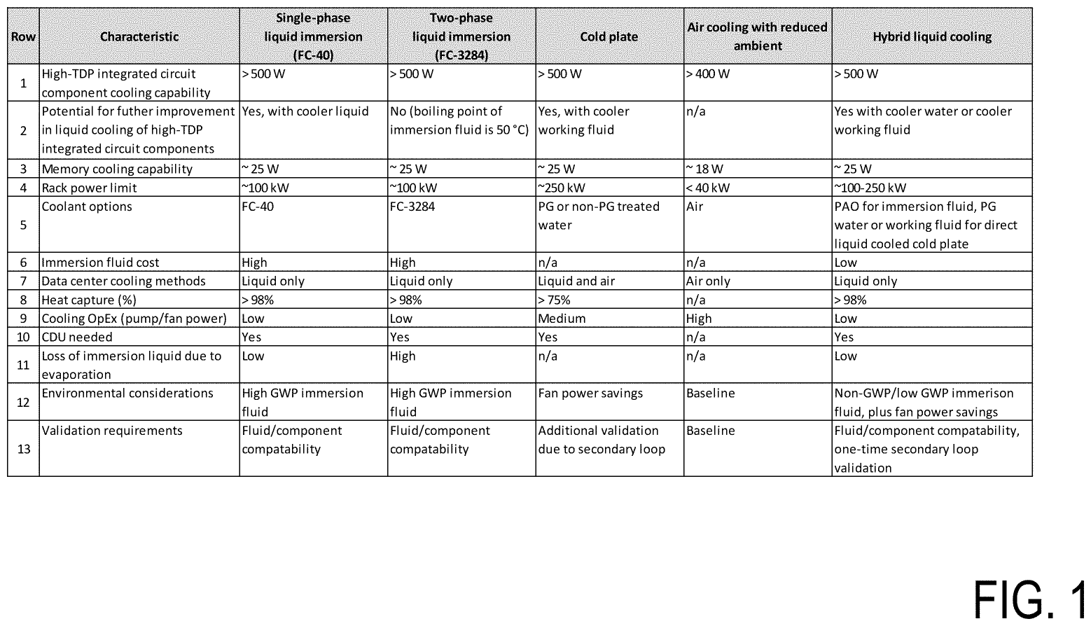

FIG. 1 is a table comparing characteristics of various available cooling solutions—single-phase and two-phase liquid immersion, cold plate, air cooling with reduced temperature ambient (e.g., 27° C.), and hybrid liquid cooling (the technologies disclosed herein). Row 1 lists the high-TDP cooling capability for the various options. Several options can provide adequate cooling for a >500 W integrated circuit component. The technologies disclosed herein may aid in providing adequate cooling for integrated circuit components having a TDP greater than 500 W. The potential for further improvements in the liquid cooling of high-TDP components is listed in row 2. Row 3 lists the cooling capability of each option to cool dual in-line memory modules (DIMMs) located on the same system board as a >500 W TDP integrated circuit component. Row 4 lists rack cooling estimates for each option.

Row 5 lists coolant options for each liquid cooling solution. The characteristics shown in the table for the single-phase and two-phase liquid cooling implementations are for those using FC-40 and FC-3284 immersion fluids, respectively. Other immersion fluids having similar characteristics (e.g., coolant cost, component- and rack-cooling capability) can be used in single- and two-phase liquid immersion cooling implementations. A polyalphaolefin-based (PAO-based) fluid can be used as the immersion fluid in the hybrid liquid cooling technologies disclosed herein. “PG water” in row 5 refers to water with propylene glycol mixed in. Row 6 lists coolant costs. The FC-40 and FC-3284 immersion fluids used in the single-phase and two-phase immersion cooling options are considerably more expensive than the PAO-based immersion fluids that can be used in the hybrid liquid cooling solution. Row 7 lists the cooling mechanisms (air, water) relied upon for each option for data center cooling. Row 8 lists the percentage of component-generated heat that can be captured by the cooling liquid. Row 9 lists a level of operating expense for providing pump and/or fan power for each cooling option. The liquid cooling options have operational expenses related to powering pumps that circulate an immersion fluid or a working fluid in the direct liquid cooling loops and cooling options with an air-cooling component have operational expenses associated with an operating fan to circulate the air. Row 10 lists whether a cooling distribution unit (CDU) is needed.

Rows 11 and 12 list environmental considerations for each cooling option. The single- and two-phase immersion cooling options utilize high-GWP immersion fluids while the hybrid liquid cooling option uses either non-GWP or low-GWP immersion fluid. Row 13 lists validation requirements for each option. Validation that the immersion fluid is compatible with integrated circuit components is a requirement for cooling options that comprise a liquid cooling component and additional validation is needed for cooling options that comprise direct liquid cooling loops, although this validation may only need to be performed once if the same liquid cooling loop design is used for all system boards. In general, the hybrid liquid cooling technologies described herein can provide high component- and rack-level cooling capabilities and low total cost of ownership while using non-flammable and/or non- or low-GWP immersion fluids.

In the following description, specific details are set forth, but embodiments of the technologies described herein may be practiced without these specific details. Well-known circuits, structures, and techniques have not been shown in detail to avoid obscuring an understanding of this description. “An embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact and “coupled” may indicate elements co-operate or interact, but they may or may not be in direct physical or electrical contact. As used herein, the phrase “thermally coupled” refers to components that are coupled to facilitate the transfer of heat, and the phrase “fluidly coupled” refers to components that are coupled to facilitate the flow of a fluid between them.

The description may use the phrases “in an embodiment,” “in embodiments,” “in some embodiments,” and/or “in various embodiments,” each of which may refer to one or more of the same or different embodiments. Furthermore, the terms “comprising,” “including,” “having,” and the like, as used with respect to embodiments of the present disclosure, are synonymous.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

Disclosed herein are hybrid liquid cooling technologies that provide two cooling mechanisms for integrated circuit components immersed in an immersion fluid. The first cooling mechanism, which provides cooling for all integrated circuit components immersed in the immersion fluid, is the dissipation of heat generated by the integrated circuit components to the immersion fluid. The second cooling mechanism is the absorption of heat generated by integrated circuit components by a working fluid flowing through direct liquid cooling loops coupled to the integrated circuit components.

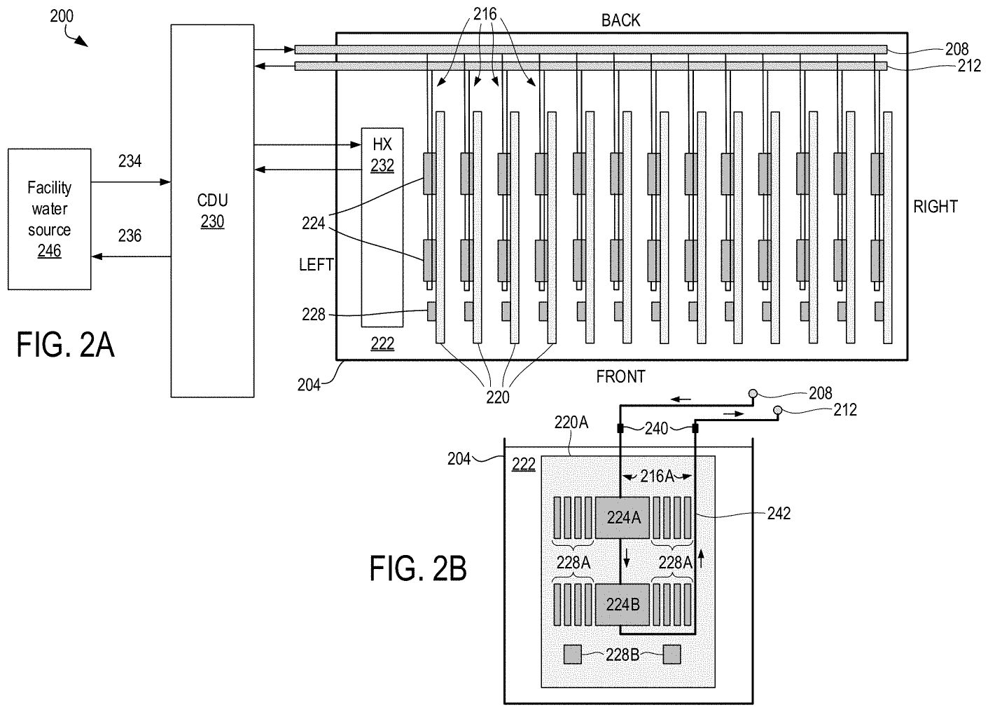

FIGS. 2A and 2B illustrate an example hybrid liquid cooling system. FIG. 2A illustrates a hybrid liquid cooling system 200 to cool a plurality of system boards 220 located within an open bath immersion tank 204. The hybrid liquid cooling system 200 comprises an open bath immersion tank 204, a supply manifold 208, a return manifold 212, and a plurality of direct liquid cooling loops 216. The system boards 220 are vertically arranged within the open bath immersion tank 204. The portion of FIG. 2A comprising the system boards 220 and the open bath immersion tank 204 represents a top view of the system boards 220 and the immersion tank 204, with the labels “front”, “back”, “left”, and “right” indicating the sides of the immersion tank 204. The immersion tank 204 can be any open bath immersion tank that is large enough to accommodate the components to be located in the tank (system boards, direct liquid cooling loops, heat exchanger, etc.) and that satisfy other immersion tank design constraints (e.g., mechanically strong enough to support the weight of the immersion fluid and components placed in the tank). In some embodiments, the immersion tank 204 meets open compute platform (OCP) immersion tank design guidelines.

The supply manifold 208 and the return manifold 212 connect to the plurality of direct liquid cooling loops 216. Each system board 220 comprises one or more first integrated circuit components 224 attached to the system board 220. The first integrated circuit components are physically and thermally coupled to one or more cold plates (not shown) that are part of one of the direct liquid cooling loops 216. Each system board 220 further comprises one or more second integrated circuit components 228 attached to the board that are not physically or thermally coupled to any of the direct liquid cooling loops 216. In some embodiments, individual first integrated circuit components 224 are thermally coupled to a cold plate of a direct liquid cooling loop 216 via a thermal interface material (TIM) layer located between the first integrated circuit component 224 and the cold plate. A TIM layer can be any suitable material, such as a silver thermal compound, thermal grease, phase change materials, indium foils, or graphite sheets. A cold plate can be any suitable type of cold plate, such as a tubed cold plate or a cold plate comprising internal fins or channels (e.g., microchannels) and be made of any suitable material, such as copper, aluminum, or stainless steel, that is chemically compatible with immersion and working fluids. A first integrated circuit component 224 can be physically coupled to a cold plate via one or more fasteners (e.g., screws) that secure the cold plate to a module, bracket, printed circuit board, or another component to which the first integrated circuit component 224 is secured via a socket, direct attachment, or otherwise.

When the system 200 is operating, the immersion tank 204 is at least partially filled with an immersion fluid 222 and the first and second integrated circuit components 224 and 228 are immersed in the immersion fluid 222. In some embodiments, a portion of the system boards 220 on which no integrated circuit components are attached or on which integrated circuit components that are not to be cooled are attached are not immersed in the immersion fluid 222.

Heat generated by the first integrated circuit components 224 is absorbed by a working fluid that flows through the cold plates coupled to the first integrated circuit components 224. Some of the heat generated by the first integrated circuit components 224 may be dissipated to the immersion fluid 222 as the first integrated circuit components 224 are immersed in the immersion fluid 222, but the direct liquid cooling loops 216 provide the primary cooling mechanism for the first integrated circuit components 224. Dissipation of heat into the immersion fluid 222 is the mechanism by which the second integrated circuit components 228 are cooled. The second integrated circuit components 228 can be physically and thermally coupled to heat sinks (e.g., air-cooled heat sinks) to aid the dissipation of heat into the immersion fluid 222. In some embodiments, a second integrated circuit component 228 can be physically and thermally coupled to a heat sink in a manner similar to how a first integrated circuit component is physically (e.g., via fasteners) and thermally (e.g., via a TIM layer) coupled to a cold plate. In some embodiments, a second integrated circuit component 228 is physically coupled to a heat sink without the use of fasteners and a TIM layer is relied upon to couple a second integrated circuit component 228 physically and thermally to the heat sink.

A cooling distribution unit (or coolant distribution unit, CDU) 230 is fluidly coupled to the supply and return manifolds 208 and 212. The CDU 230 provides (e.g., pumps) a first working fluid to the supply manifold 208. The first working fluid passes through the direct liquid cooling loops 216 where it absorbs the heat generated by the first integrated circuit components 224. Heated first working fluid exits the direct liquid cooling loops 216 and enters the return manifold 212. The CDU 230 receives the heated first working fluid from the return manifold 212, cools the first working fluid, and returns the first working fluid to the supply manifold 208. The first working fluid can be a single-phase or two-phase working fluid and is chemically compatible with the immersion fluid 222. In some embodiments, the CDU 230 can be fluidly coupled to the supply and return manifolds 208 and 212 via global supply and return manifolds that are separate from the supply and return manifolds 208 and 212 that are local to the immersion tank 204. The global supply and return manifolds can supply the first working fluid to multiple immersion tanks to cool the integrated circuit components located therein.

A heat exchanger (HX) 232 located within the immersion tank 204 utilizes a second working fluid provided by the CDU 230 to remove heat from the immersion fluid 222. The CDU 230 receives heated second working fluid from the heat exchanger 232, cools the second working fluid, and returns the second working fluid to the heat exchanger 232 for further cooling of the immersion fluid 222. The CDU 230 uses coolant (e.g., facility service water) provided to the CDU 230 by a supply line 234 to carry heat extracted from the first and second working fluids by the CDU 230 away from the CDU 230. The coolant is carried away from the CDU 230 by a return line 236.

Although the CDU 230 in FIG. 2A is shown as providing first and second working fluids to the direct liquid cooling loops 216 and the heat exchanger 232, in some embodiments, the first and second working fluids can be provided to the cooling loops 216 and the heat exchanger 232 from separate sources. For example, a first CDU can provide a first working fluid to the direct liquid cooling loops 216 and a second CDU can provide a second working fluid to the heat exchanger 232. In another example, the heat exchanger 232 is connected to the facility water source 246 and the second working fluid is the facility water provided by the facility water source 246. In some embodiments, a single CDU can support multiple immersion tanks. That is, a single CDU can be fluidly connected to one or more additional supply manifolds and one or more additional return manifolds to provide a working fluid to direct liquid cooling loops located within the one or more additional immersion tanks.

In some embodiments, the immersion fluid 222 is a highly dielectric fluid that has one or more of the following characteristics: widely available, biodegradable, recyclable, low cost, GWP of less than one, and non-flammable. The immersion fluid 222 can circulate within the open bath immersion tank 204 via natural or forced convection. In forced convection embodiments, a single pump can be used to circulate the immersion fluid 222 in the tank 204. In some embodiments, multiple pumps can be used to circulate the immersion fluid 222 with the tank 204, but with the plurality of system boards 220 being located within a single tank, the number of pumps is less than the number of system boards.

FIG. 2B illustrates the flow of working fluid through one of the direct liquid cooling loops 216. The direct liquid cooling loop 216 can comprise one or more conduits that form a loop from the supply manifold 208 to the return manifold 212 and one or more cold plates coupled to the first integrated circuit components 224. The working fluid exits the supply manifold 208 where it is routed to a system board 220A and enters the loop 216A. The system board 220A comprises first integrated circuit components 224A and 224B, which are high-TDP processor units, and second integrated circuit components 228 (DIMMs 228A and additional second integrated circuit components 228B). The working fluid flows through cold plates attached to the first integrated circuit components 224A and 224B, where it absorbs heat generated by these components, and follows a return path 242 to the return manifold 212.

The direct liquid cooling loop 216 connects to the supply and return manifolds 208 and 212 via connectors, such as connectors 240. In some embodiments, the connectors 240 comprise quick disconnect fittings that allow for the easy addition and removal of the system board 220 to the system 200. For example, after the system board 220 is placed in the immersion tank 204, the direct liquid cooling loop 216 is easily connected to the supply and return manifolds 208 and 216 via the connectors 240 via quick disconnect fittings. The connectors 240 can comprise a single quick disconnect fitting or a conduit (e.g., a flexible tube) with quick disconnect fittings at either end. In other embodiments, the system boards 220 can connect to the supply and return manifolds 208 and 212 via other mechanisms.

By being able to connect system boards individually to supply and return manifolds, the hybrid liquid cooling technologies disclosed herein provide for an interchangeable hybrid liquid cooling solution. For example, the decision of whether to have a system board's components be cooled only through immersion fluid cooling or through immersion fluid cooling combined with direct liquid cooling can be made on a board-by-board basis. Boards comprising high-TDP components that cannot be sufficiently cooled by the immersion liquid can comprise direct liquid cooling loops that couple to the high-TDP components and boards comprising components that can all be cooled sufficiently without relying upon direct liquid cooling can be left without a direct liquid cooling loop coupled to them. Thus, a hybrid liquid cooling system can comprise a mixture of system boards that do and do not have direct liquid cooling loops coupled to them.

The liquid cooling system 200 comprising the plurality of system boards 220 can be considered a rack system. A rack system can comprise as few as one system board and up to as many system boards as the cooling capabilities and the physical characteristics (e.g., size of the immersion tank, number of direct liquid cooling loops that the CDU can support) that the cooling system 200 allows.

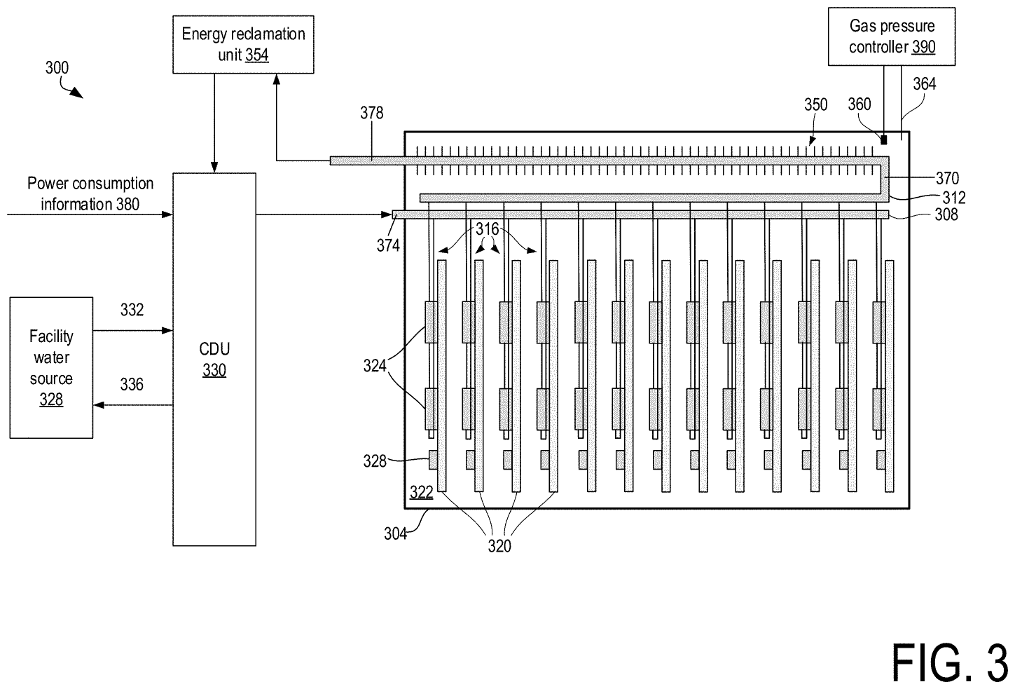

FIG. 3 is an example hybrid liquid cooling system comprising an energy reclamation unit. The liquid cooling system 300 comprises similar components as the liquid cooling system 200 in addition to an energy reclamation unit 354 that converts heat captured by a two-phase working fluid that flows through direct liquid cooling loops to electricity. The cooling system 300 comprises a closed bath immersion tank 304, a supply manifold 308, and a return manifold 312. The supply and return manifolds 308 and 312 are connected to a plurality of direct liquid cooling loops 316 vertically arranged within the closed bath immersion tank 304. The direct liquid cooling loops 316 are coupled to a first set of integrated circuit components 324 attached to the system boards 320. The system boards 320 further comprise a second set of integrated circuit components 328 attached to the system boards 320 that are not physically or thermally coupled to any of the direct liquid cooling loops 316. The first integrated circuit components 324 are physically and thermally coupled to cold plates that are part of the direct liquid cooling loops 316 and the second integrated circuit components can be coupled to air-cooled heat sinks that facilitate the dissipation of heat generated by the second integrated circuit component to a two-phase immersion fluid 322.

The system 300 further comprises a gas pressure sensor 360 located in the immersion tank that provides gas pressure sensor data indicating a gas pressure above the immersion fluid 322 and a gas inlet 364 to provide pressurized inert gas into the closed bath immersion tank 304. A gas pressure controller 390 controls the flow of inert gas into the immersion tank 304 based on the gas pressure sensor data provided by the gas pressure sensor 360 and can maintain a target gas pressure above the immersion fluid to maintain the boiling point of the immersion fluid 322. In some embodiments, an orchestration environment can receive the gas pressure sensor data and provide gas flow control information to the gas pressure controller 390 that the controller 390 can use to control the flow of the inert gas into the tank 304. In some embodiments, the gas pressure sensor 360 is located on one of the system boards 320 and a baseboard management controller (BMC) provides the gas pressure sensor data to the gas pressure controller 390 or an orchestration environment. In some embodiments, gas flow control information can be generated and provided to the gas pressure controller according to DCIM protocols.

A cooling distribution unit (CDU) 330 is fluidly coupled to the supply manifold 308 to provide the two-phase working fluid to the direct liquid cooling loops 316. The return manifold 312 is fluidly coupled to the energy reclamation unit 354 to carry the working fluid heated by the first integrated circuit components to the energy reclamation unit 354. The return manifold 312 comprises a condenser 350 that extracts heat from the immersion fluid 322 that the immersion fluid 322 has absorbed from the second integrated circuit components 328. This extracted heat is absorbed by the two-phase working fluid as it flows through the return manifold 312 to the energy reclamation unit 354.

In some embodiments, the two-phase immersion fluid and the two-phase working fluid possess the temperatures and vapor qualities at various points in the system as follows. As the working fluid is a two-phase working fluid, the system 300 can provide the working fluid to the supply manifold 308 at a higher temperature (e.g., greater than 50° C.). The working fluid is supplied to the supply manifold as a saturated liquid or as a liquid-vapor mixture that is predominantly liquid. At a point in the return manifold 312 after where the direct liquid cooling loops 316 connect to the return manifold 312 and before where the working fluid absorbs heat from the condenser 350 (e.g., at a point 370), the working fluid can have a high vapor quality (e.g., ˜80-90%) and still be at the same temperature it was as it entered the supply manifold 308 (e.g., at a point 374). As the working fluid passes through the condenser 350, it absorbs heat from the immersion fluid 322. The condenser 350 is located above the immersion fluid 322 and is thus exposed to immersion fluid vapor. The heat extracted from the immersion fluid vapor by the condenser 350 is first absorbed by the working fluid as latent heat. Once the remaining working fluid liquid has been turned to gas, the remaining heat extracted by the immersion fluid vapor by the condenser is absorbed as sensible heat that raises the temperature of the working fluid vapor.

After passing through the condenser 350 (e.g., at a point 378), the working fluid can have a vapor quality of 100% (been entirely converted to gas) and have a temperature suitable for use by the energy reclamation unit 354 (e.g., >60° C.). In other embodiments, the working fluid can have a different temperature and/or different vapor quality upon exit from the direct liquid cooling loops 316 or after passing through the condenser 350. The condenser 350 can comprise one or more condenser coils.

To achieve a desired temperature and/or vapor quality for the working fluid as it enters the energy reclamation unit 354, the CDU 330 can adjust the flow rate (e.g., via microcontrollers located within the CDU 330) of the working fluid based on an amount of power consumed by the integrated circuit components immersed in the immersion tank 304. Generally, the working fluid flow rate can be increased as the integrated circuit components power consumption increase to prevent the working fluid from arriving at the energy reclamation unit 354 with too high a temperature or to prevent the working fluid from having too high a temperature as it flows through the condenser 350, which could prevent the working fluid from absorbing an adequate amount of heat from the immersion fluid 322 to keep the second integrated circuit components 328 cooled.

The CDU 330 can receive power consumption information 380 that indicates an amount of integrated circuit component power consumption. The amount of integrated circuit component power consumption can comprise integrated circuit component-level, system board-level, and/or rack-level power consumption information. The power consumption information 380 can be based on component- or board-level performance metrics or expected component- or board-level power consumption levels based on the workloads and/or applications executing or to be executed on the integrated circuit components. The power consumption information 380 can be provided to the CDU 330 by one or more of the system boards 320, a rack-level controller, or an orchestration environment that manages data center resources. Baseboard management controllers (BMCs) located on the system boards 320 can provide power consumption metrics or other power-related information to the CDU 330, the rack-level controller, or an orchestration environment element. In some embodiments, the power consumption information 380 can be provided by a software-defined network (SDN) controller or network function virtualization (NFV) infrastructure (NFVI) element (e.g., NFV orchestrator (NFVO), virtualized infrastructure manager (VIM), virtual network function manager (VNFM)). In some embodiments, the power consumption information 380 can be generated and/or provided in compliance with data center infrastructure management (DCIM) protocols.

In some embodiments, control of the working fluid flow rate can further be based on temperature sensor data provided by one or more temperature sensors located in the system 300. These temperature sensors can be located in the supply manifold 308, the return manifold 312, the immersion tank 304, or elsewhere. In some embodiments, a CDU 330 can receive flow rate control information instead of power consumption information 380 to control the working fluid flow rate. Flow rate control information can be determined by an orchestration environment or rack-controller and be based on integrated circuit component power consumption.

The energy reclamation unit 354 can convert the working fluid's thermal energy into electricity. In some embodiments, the working fluid passes through an organic Rankine cycle electricity generator to produce electricity. The produced electricity can be used to power components of the hybrid liquid cooling system (e.g., CDU pump, immersion tank pump) and/or components belonging to the infrastructure of the facility housing the hybrid liquid cooling system, such as fans or motors belonging to coolers, condensers, towers, etc. Reclaiming the thermal energy captured by the working fluid to help power a hybrid liquid cooling system or facility infrastructure can reduce a facility's PUE and reduce a data center operator's total cost of ownership.

The energy reclamation unit 354 is fluidly coupled to the CDU 330 to return the working fluid to the CDU 330. Facility water or another coolant can be provided via supply and return lines 332 and 336 to remove heat from the CDU 330. As discussed above in regard to FIGS. 2A & 2B, the CDU 330 can provide the working fluid to direct liquid cooling loops in multiple immersion tanks, the heat exchanger 332 can receive a working fluid from a CDU or other source separate from the CDU that provides the direct liquid cooling working fluid. In some embodiments, the energy reclamation unit 354 reclaims 10% or more of the heat generated by the integrated circuit components captured by the working fluid.

The hybrid and interchangeable liquid cooling technologies described herein may provide at least the following advantages. First, they provide a liquid cooling strategy that may provide cooling for a combination of high-TDP processor units (e.g., 600 W GPU modules that comply with the Open Compute Platform Accelerator Module (OAM), 350 W server CPUs with integrated high bandwidth memory (HBM)), and high-TDP DIMMs, while capturing a high degree of the heat generated by these components (e.g., up to 98%). Second, the use of cold plates in the direct liquid cooling loop with relatively low cost single-phase immersion fluids may lead to a low total cost of ownership (as measured by, for example, performance-per-dollar or cost-per virtual machine core) as they can support the cooling of high-TDP integrated circuit components or high-performance integrated circuit component stock-keeping units (SKUs). Third, the disclosed liquid cooling technologies may provide OEMs with interchangeable liquid cooling systems. Fourth, in some embodiments, integrated circuit components may be able to be cooled using warmer immersion fluids (e.g., ASHRAE class W4 fluids), depending on the components used, such as the type of cold plate used, in a particular liquid cooling implementation. Fourth, by providing liquid cooling of high-TDP components with the use of non-GWP or low-GWP fluids, the disclosed technologies may aid companies in reaching environmental sustainability goals. The reclamation of heat captured by direct liquid cooling to power the liquid cooling systems of facility infrastructure may further assist a company in reaching sustainability goals. Fifth, by adjusting the working fluid flow rate through the direct cooling loops to control the temperature and vapor quality of the working fluid as it enters an energy reclamation unit, control of the flow rate at the board level, or adjustment of the power consumed at the component-level may not be needed. That is, adjustment of the working fluid flow rate may provide a rack-level solution to ensure working fluid arrives at an energy reclamation unit having a suitable temperature and vapor quality.

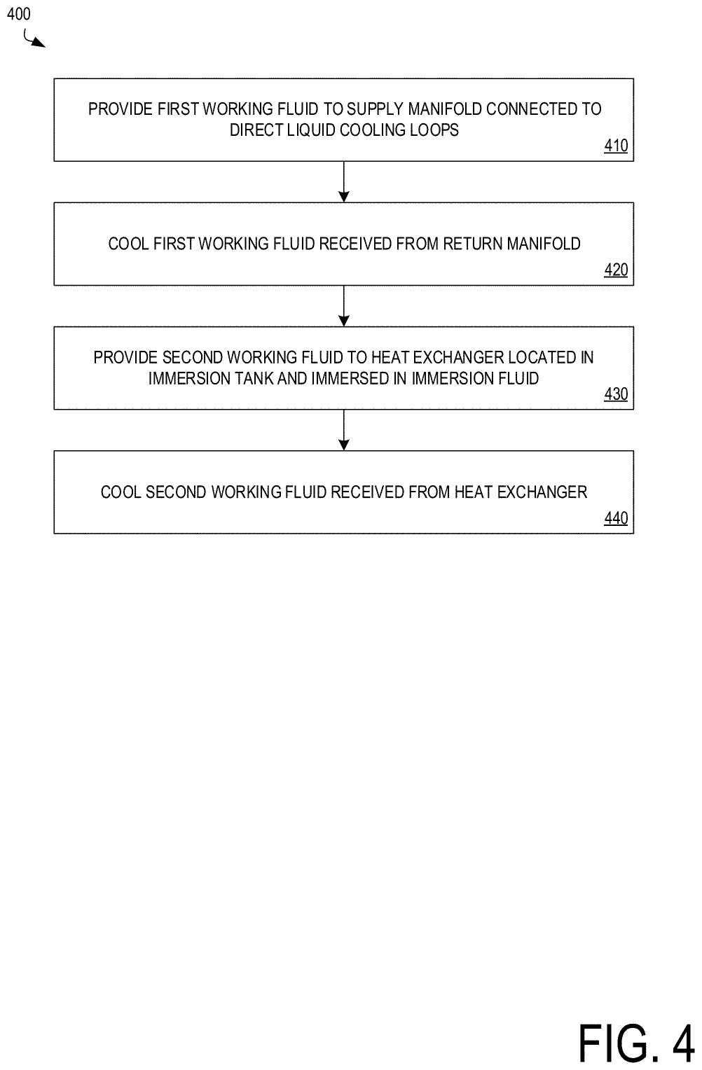

FIG. 4 is a flowchart of an example hybrid liquid cooling method. The method 400 can be performed by a hybrid liquid cooling system located in a data center. At 410, a first working fluid is provided to a supply manifold. At 420, the first working fluid received from a return manifold is cooled. The supply manifold and the return manifold are connected to a plurality of direct liquid cooling loops physically and thermally coupled to a first plurality of integrated circuit components located within an immersion tank at least partially filled with an immersion fluid. The first plurality of integrated circuit components is immersed in the immersion fluid and the first working fluid is heated by the first plurality of integrated circuit components. At 430, a second working fluid is provided to a heat exchanger located within the immersion tank and immersed in the immersion fluid. At 440, the second working fluid received from the heat exchanger is cooled. A second plurality of integrated circuit components are located within the immersion tank and immersed within the immersion fluid. The second plurality of integrated circuit components is not physically and thermally coupled to the plurality of liquid loops.

In other embodiments, the method 400 can comprise one or more additional elements. For example, the method 400 can further comprise adjusting a flow rate of the working fluid to the supply manifold based on integrated circuit power consumption information. In another example, the method 400 can further comprise adjusting a flow of pressurized inert gas into a closed bath immersion tank based on gas pressure sensor data indicating a gas pressure above the immersion fluid.

The technologies described herein can be performed by or implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment). As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that host companies applications and data), and an edge data center (e.g., a data center, typically having a smaller footprint than other data center types, located close to the geographic area that it serves).

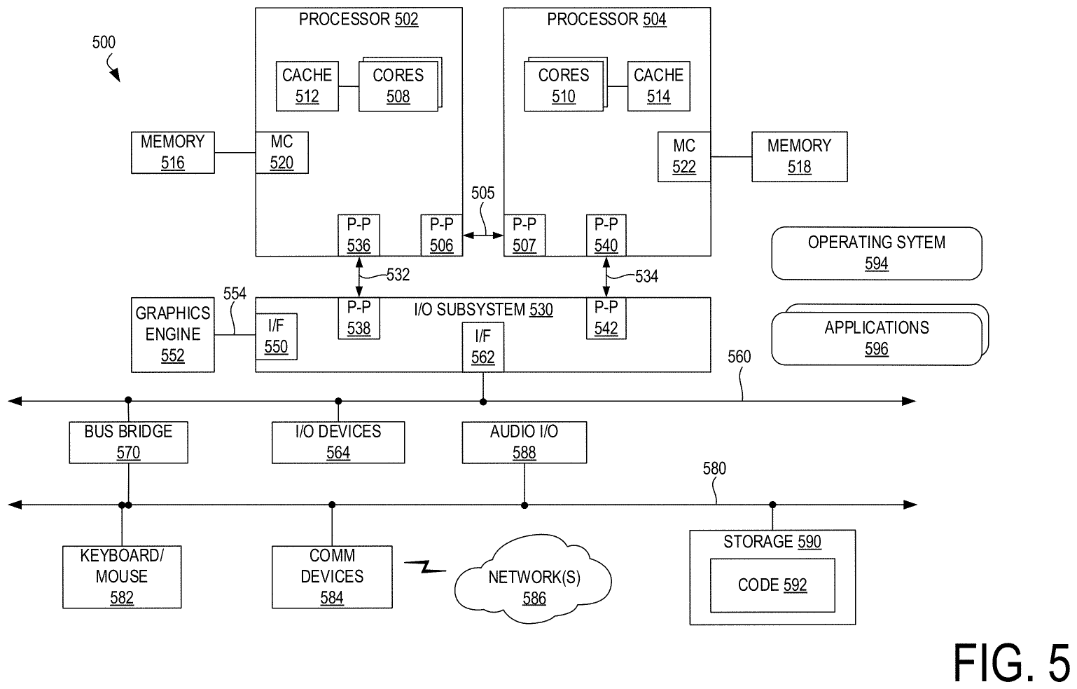

FIG. 5 is a block diagram of an example computing system that can be cooled by a hybrid liquid cooling system or that can provide working fluid flow rate control or gas pressure control in a hybrid liquid computing system. Generally, components shown in FIG. 5 can communicate with other shown components, although not all connections are shown, for ease of illustration. The computing system 500 is a multiprocessor system comprising a first processor unit 502 and a second processor unit 504 comprising point-to-point (P-P) interconnects. A point-to-point (P-P) interface 506 of the processor unit 502 is coupled to a point-to-point interface 507 of the processor unit 504 via a point-to-point interconnection 505. It is to be understood that any or all of the point-to-point interconnects illustrated in FIG. 5 can be alternatively implemented as a multi-drop bus, and that any or all buses illustrated in FIG. 5 could be replaced by point-to-point interconnects.

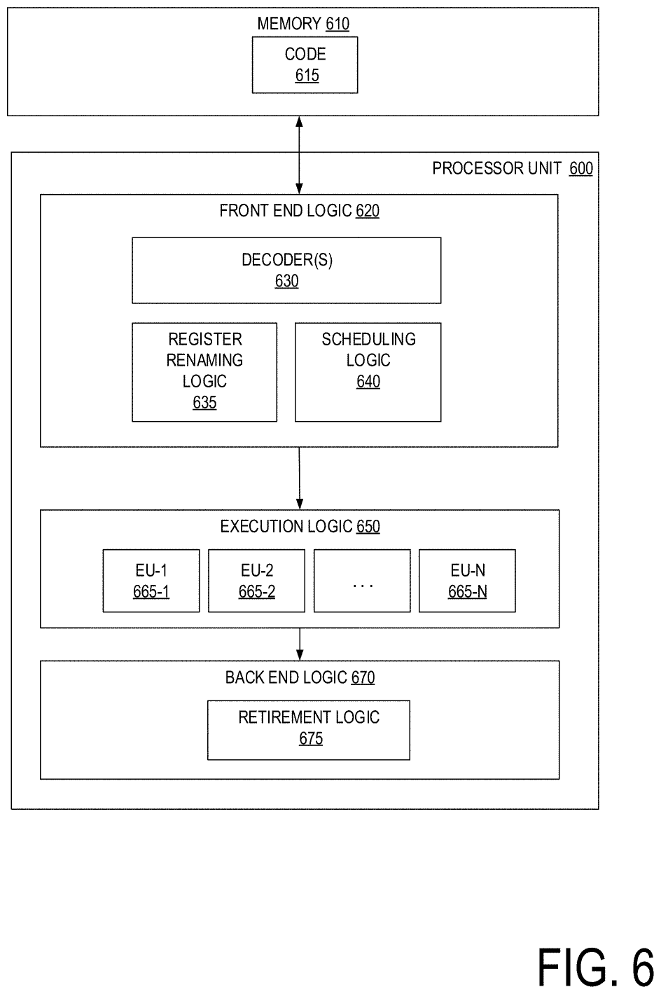

The processor units 502 and 504 comprise multiple processor cores. Processor unit 502 comprises processor cores 508 and processor unit 504 comprises processor cores 510. Processor cores 508 and 510 can execute computer-executable instructions in a manner similar to that discussed below in connection with FIG. 6, or other manners.

Processor units 502 and 504 further comprise cache memories 512 and 514, respectively. The cache memories 512 and 514 can store data (e.g., instructions) utilized by one or more components of the processor units 502 and 504, such as the processor cores 508 and 510. The cache memories 512 and 514 can be part of a memory hierarchy for the computing system 500. For example, the cache memories 512 can locally store data that is also stored in a memory 516 to allow for faster access to the data by the processor unit 502. In some embodiments, the cache memories 512 and 514 can comprise multiple cache levels, such as level 1 (L1), level 2 (L2), level 3 (L3), level 4 (L4), and/or other caches or cache levels, such as a last level cache (LLC). Some of these cache memories (e.g., L2, L3, L4, LLC) can be shared among multiple cores in a processor unit. One or more of the higher levels of cache levels (the smaller and faster caches) in the memory hierarchy can be located on the same integrated circuit die as a processor core and one or more of the lower cache levels (the larger and slower caches) can be located on an integrated circuit dies that are physically separate from the processor core integrated circuit dies.

Although the computing system 500 is shown with two processor units, the computing system 500 can comprise any number of processor units. Further, a processor unit can comprise any number of processor cores. A processor unit can take various forms such as a central processing unit (CPU), a graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other types of processing units. As such, the processor unit can be referred to as an XPU (or xPU). Further, a processor unit can comprise one or more of these various types of processing units. In some embodiments, the computing system comprises one processor unit with multiple cores, and in other embodiments, the computing system comprises a single processor unit with a single core. As used herein, the terms “processor unit” and “processing unit” can refer to any processor, processor core, component, module, engine, circuitry, or any other processing element described or referenced herein.

In some embodiments, the computing system 500 can comprise one or more processor units that are heterogeneous or asymmetric to another processor unit in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processor units in a system.

The processor units 502 and 504 can be located in a single integrated circuit component (such as a multi-chip package (MCP) or multi-chip module (MCM)) or they can be located in separate integrated circuit components. An integrated circuit component comprising one or more processor units can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor unit, or on one or more integrated circuit dies separate from the integrated circuit dies comprising the processor units. In some embodiments, these separate integrated circuit dies can be referred to as “chiplets”. In some embodiments where there is heterogeneity or asymmetry among processor units in a computing system, the heterogeneity or asymmetric can be among processor units located in the same integrated circuit component. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Processor units 502 and 504 further comprise memory controller logic (MC) 520 and 522. As shown in FIG. 5, MCs 520 and 522 control memories 516 and 518 coupled to the processor units 502 and 504, respectively. The memories 516 and 518 can comprise various types of volatile memory (e.g., dynamic random-access memory (DRAM), static random-access memory (SRAM)) and/or non-volatile memory (e.g., flash memory, chalcogenide-based phase-change non-volatile memories), and comprise one or more layers of the memory hierarchy of the computing system. While MCs 520 and 522 are illustrated as being integrated into the processor units 502 and 504, in alternative embodiments, the MCs can be external to a processor unit.

Processor units 502 and 504 are coupled to an Input/Output (I/O) subsystem 530 via point-to-point interconnections 532 and 534. The point-to-point interconnection 532 connects a point-to-point interface 536 of the processor unit 502 with a point-to-point interface 538 of the I/O subsystem 530, and the point-to-point interconnection 534 connects a point-to-point interface 540 of the processor unit 504 with a point-to-point interface 542 of the I/O subsystem 530. Input/Output subsystem 530 further includes an interface 550 to couple the I/O subsystem 530 to a graphics engine 552. The I/O subsystem 530 and the graphics engine 552 are coupled via a bus 554.

The Input/Output subsystem 530 is further coupled to a first bus 560 via an interface 562. The first bus 560 can be a Peripheral Component Interconnect Express (PCIe) bus or any other type of bus. Various I/O devices 564 can be coupled to the first bus 560. A bus bridge 570 can couple the first bus 560 to a second bus 580. In some embodiments, the second bus 580 can be a low pin count (LPC) bus. Various devices can be coupled to the second bus 580 including, for example, a keyboard/mouse 582, audio I/O devices 588, and a storage device 590, such as a hard disk drive, solid-state drive, or another storage device for storing computer-executable instructions (code) 592 or data. The code 592 can comprise computer-executable instructions for performing methods described herein. Additional components that can be coupled to the second bus 580 include communication device(s) 584, which can provide for communication between the computing system 500 and one or more wired or wireless networks 586 (e.g., Wi-Fi, cellular, or satellite networks) via one or more wired or wireless communication links (e.g., wire, cable, Ethernet connection, radio-frequency (RF) channel, infrared channel, Wi-Fi channel) using one or more communication standards (e.g., IEEE 502.11 standard and its supplements).

In embodiments where the communication devices 584 support wireless communication, the communication devices 584 can comprise wireless communication components coupled to one or more antennas to support communication between the computing system 500 and external devices. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The system 500 can comprise removable memory such as flash memory cards (e.g., SD (Secure Digital) cards), memory sticks, Subscriber Identity Module (SIM) cards). The memory in system 500 (including caches 512 and 514, memories 516 and 518, and storage device 590) can store data and/or computer-executable instructions for executing an operating system 594 and application programs 596. Example data includes web pages, text messages, images, sound files, and video data to be sent to and/or received from one or more network servers or other devices by the system 500 via the one or more wired or wireless networks 586, or for use by the system 500. The system 500 can also have access to external memory or storage (not shown) such as external hard drives or cloud-based storage.

The operating system 594 can control the allocation and usage of the components illustrated in FIG. 5 and support the one or more application programs 596. The application programs 596 can include common computing system applications (e.g., email applications, calendars, contact managers, web browsers, messaging applications) as well as other computing applications.

The computing system 500 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. Other possible input and output devices include piezoelectric and other haptic I/O devices. Any of the input or output devices can be internal to, external to, or removably attachable with the system 500. External input and output devices can communicate with the system 500 via wired or wireless connections.

In addition, the computing system 500 can provide one or more natural user interfaces (NUIs). For example, the operating system 594 or applications 596 can comprise speech recognition logic as part of a voice user interface that allows a user to operate the system 500 via voice commands. Further, the computing system 500 can comprise input devices and logic that allows a user to interact with computing the system 500 via body, hand or face gestures.

The system 500 can further include at least one input/output port comprising physical connectors (e.g., USB, IEEE 1394 (FireWire), Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 500 can further comprise one or more additional antennas coupled to one or more additional receivers, transmitters, and/or transceivers to enable additional functions.

It is to be understood that FIG. 5 illustrates only one example computing system architecture. Computing systems based on alternative architectures can be used to implement technologies described herein. For example, instead of the processors 502 and 504 and the graphics engine 552 being located on discrete integrated circuits, a computing system can comprise an SoC (system-on-a-chip) integrated circuit incorporating multiple processors, a graphics engine, and additional components. Further, a computing system can connect its constituent component via bus or point-to-point configurations different from that shown in FIG. 5. Moreover, the illustrated components in FIG. 5 are not required or all-inclusive, as shown components can be removed and other components added in alternative embodiments.

FIG. 6 is a block diagram of an example processor unit 600 to execute computer-executable instructions as part of implementing technologies described herein. The processor unit 600 can be a single-threaded core or a multithreaded core in that it may include more than one hardware thread context (or “logical processor”) per processor unit.

FIG. 6 also illustrates a memory 610 coupled to the processor unit 600. The memory 610 can be any memory described herein or any other memory known to those of skill in the art. The memory 610 can store computer-executable instructions 615 (code) executable by the processor core 600.

The processor unit comprises front-end logic 620 that receives instructions from the memory 610. An instruction can be processed by one or more decoders 630. The decoder 630 can generate as its output a micro-operation such as a fixed width micro operation in a predefined format, or generate other instructions, microinstructions, or control signals, which reflect the original code instruction. The front-end logic 620 further comprises register renaming logic 635 and scheduling logic 640, which generally allocate resources and queues operations corresponding to converting an instruction for execution.

The processor unit 600 further comprises execution logic 650, which comprises one or more execution units (EUs) 665-1 through 665-N. Some processor unit embodiments can include a number of execution units dedicated to specific functions or sets of functions. Other embodiments can include only one execution unit or one execution unit that can perform a particular function. The execution logic 650 performs the operations specified by code instructions. After completion of execution of the operations specified by the code instructions, back-end logic 670 retires instructions using retirement logic 675. In some embodiments, the processor unit 600 allows out of order execution but requires in-order retirement of instructions. Retirement logic 675 can take a variety of forms as known to those of skill in the art (e.g., re-order buffers or the like).

The processor unit 600 is transformed during execution of instructions, at least in terms of the output generated by the decoder 630, hardware registers and tables utilized by the register renaming logic 635, and any registers (not shown) modified by the execution logic 650.

As used herein, the term “module” refers to logic that may be implemented in a hardware component or device, software or firmware running on a processor unit, or a combination thereof, to perform one or more operations consistent with the present disclosure. Software and firmware may be embodied as instructions and/or data stored on non-transitory computer-readable storage media. As used herein, the term “circuitry” can comprise, singly or in any combination, non-programmable (hardwired) circuitry, programmable circuitry such as processor units, state machine circuitry, and/or firmware that stores instructions executable by programmable circuitry. Modules described herein may, collectively or individually, be embodied as circuitry that forms a part of a computing system. Thus, any of the modules or controllers can be implemented as circuitry, such as gas pressure controller circuitry or working fluid flow rate controller circuitry. A computing system referred to as being programmed to perform a method can be programmed to perform the method via software, hardware, firmware, or combinations thereof.

Any of the disclosed methods (or a portion thereof) can be implemented as computer-executable instructions or a computer program product. Such instructions can cause a computing system or one or more processor units capable of executing computer-executable instructions to perform any of the disclosed methods. As used herein, the term “computer” refers to any computing system or device described or mentioned herein. Thus, the term “computer-executable instruction” refers to instructions that can be executed by any computing system or device described or mentioned herein.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

The computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus, comprising: an open bath immersion tank; a supply manifold connected to a plurality of direct liquid cooling loops; a return manifold connected to the direct liquid cooling loops; a plurality of system boards located within the open bath immersion tank, individual of the system boards comprising: one or more first integrated circuit components physically and thermally coupled to one of the direct liquid cooling loops; and one or more second integrated circuit components not physically or thermally coupled to any of the direct liquid cooling loops; and a heat exchanger located within the open bath immersion tank.

Example 2 comprises the apparatus of Example 1, wherein individual of the direct liquid cooling loops comprise one or more cold plates and for individual of the system boards, the first integrated circuit components are thermally coupled to the cold plates of one of the direct liquid cooling loops.

Example 3 comprises the apparatus of Example 1 or 2, wherein the open bath immersion tank is at least partially filled with an immersion fluid and the one or more first integrated circuit components and the one or more second integrated circuit components of individual of the system boards are immersed in the immersion fluid.

Example 4 comprises the apparatus of any one of Example 1-3, further comprising a single pump located within the open bath immersion tank.

Example 5 comprises the apparatus of any one of Example 1-4, wherein the direct liquid cooling loops are connected to the supply manifold and the return manifold via quick disconnect fittings.

Example 6 comprises the apparatus of any one of Example 1-5, further comprising an additional system board located within the open bath immersion tank, the additional system board comprising a third plurality of integrated circuit components comprising all integrated circuit components attached to the additional system board, wherein none of the third plurality of integrated circuit components are thermally or physically coupled to any of the direct liquid cooling loops.

Example 7 is a system comprising: an immersion tank; a supply manifold connected to a plurality of direct liquid cooling loops; a return manifold connected to the plurality of direct liquid cooling loops; a plurality of system boards located within the immersion tank, individual of the system boards comprising: one or more first integrated circuit components physically and thermally coupled to one of the direct liquid cooling loops; and one or more second integrated circuit components not physically and thermally coupled to any of the direct liquid cooling loops; a heat exchanger located within the immersion tank; and a cooling distribution unit fluidly coupled to the supply manifold to provide a working fluid to the direct liquid cooling loops.

Example 8 comprises the system of Example 7, wherein individual of the direct liquid cooling loops comprise one or more cold plates and for individual of the system boards, the first integrated circuit components are thermally coupled to the cold plates of one of the direct liquid cooling loops.

Example 9 comprises the system of Example 7 or 8, wherein the immersion tank is an open bath immersion tank.

Example 10 comprises the system of any one of Example 7-9, wherein the working fluid provided to the direct liquid cooling loops is a first working fluid and the cooling distribution unit is fluidly coupled to the heat exchanger to provide a second working fluid to the heat exchanger.

Example 11 comprises the system of any one of Example 7-10, wherein the working fluid provided to the direct liquid cooling loops is a first working fluid and wherein the heat exchanger receives a second working fluid from a source other than the cooling distribution unit.

Example 12 comprises the system of any one of Example 7-11, wherein the working fluid is a single-phase working fluid.

Example 13 comprises the system of any one of Example 7-12, wherein the working fluid is a two-phase working fluid.

Example 14 comprises the system of any one of Example 7-13, wherein the immersion tank is at least partially filled with an immersion fluid.

Example 15 comprises the system of Example 14, wherein the one or more first integrated circuit components, the one or more second integrated circuit components, and the heat exchanger are immersed in the immersion fluid.

Example 16 comprises the system of Example 14, wherein the immersion fluid is a single-phase immersion fluid.

Example 17 comprises the system of Example 14, wherein the immersion fluid is non-flammable

Example 18 comprises the system of Example 14, wherein the immersion fluid is a non-GWP (global warming potential) fluid.

Example 19 comprises the system of Example 14, wherein the immersion fluid has a GWP (global warming potential) of less than 1.

Example 20 comprises the system of Example 14, wherein: the immersion fluid is a two-phase immersion fluid; the immersion tank is a closed bath immersion tank; the return manifold comprises a condenser to condense immersion fluid vapor; and the system further comprises an energy reclamation unit fluidly coupled to the return manifold and the cooling distribution unit to receive the working fluid from the return manifold to provide the working fluid to the cooling distribution unit, the energy reclamation unit to convert thermal energy of the working fluid into electricity.

Example 21 comprises the system of any of Example 20, wherein the cooling distribution unit is to further adjust a flow rate of the working fluid to the supply manifold based on an amount of power consumed by the first integrated circuit components of at least one of the system boards.

Example 22 comprises the system of Example 20 or 21, further comprising: a gas inlet to provide a pressurized inert gas to the closed bath immersion tank; a gas pressure sensor located in the closed bath immersion tank to provide gas pressure sensor data indicating a gas pressure above the immersion fluid; and a gas pressure controller to control a flow of the pressurized inert gas to the closed bath immersion tank to maintain a target gas pressure above the immersion fluid.

Example 23 comprises the system of any one of Example 7-22, wherein the cooling distribution unit is fluidly connected to one or more additional supply manifolds to provide the working fluid to one or more pluralities of direct liquid cooling loops physically and thermally coupled to integrated circuit component attached to system boards located within one or more additional immersion tanks.

Example 24 is a method comprising: providing a first working fluid to a supply manifold; cooling the first working fluid received from a return manifold, the supply manifold and the return manifold connected to a plurality of direct liquid cooling loops physically and thermally coupled to a first plurality of integrated circuit components attached to a plurality of system boards located within an immersion tank at least partially filled with an immersion fluid, the first plurality of integrated circuit components immersed in the immersion fluid, the first working fluid heated by the first plurality of integrated circuit components; providing a second working fluid to a heat exchanger located within the immersion tank and immersed in the immersion fluid; and cooling the second working fluid received from the heat exchanger, a second plurality of integrated circuit components located within the immersion tank and immersed within the immersion fluid, the second plurality of integrated circuit components not physically and thermally coupled to the plurality of direct liquid cooling loops.

Example 25 comprises the method of Example 24, further comprising adjusting a flow rate of the first working fluid to the supply manifold based on an amount of power consumed by the first plurality of integrated circuit components of at least one of the system boards.

Example 25 comprises the method of Example 24 or 25, wherein the immersion tank is a closed bath immersion tank, the method further comprising adjusting a flow of pressurized inert gas into the closed bath immersion tank based on gas pressure sensor data provided by a gas pressure sensor indicating a gas pressure above the immersion fluid.

Example 26 is one or more non-transitory computer-readable storage media storing computer-executable instructions that, when executed, cause one or more integrated circuit components to perform any one of the methods of Example 24-26.

Example 27 is a system comprising: an open bath immersion tank at least partially filled with an immersion fluid; a heat exchanger located within the open bath immersion tank; a liquid cooling means to: provide a first liquid cooling mechanism for a plurality of first integrated circuit components attached to a plurality of system boards located within the open bath immersion tank; and provide a second liquid cooling mechanism for a plurality of second integrated circuit components attached to the system boards, the first integrated circuit components and the second integrated circuit component immersed in the immersion fluid.

Example 28 is an apparatus comprising a means to perform any one of the methods of Examples 24-26.

We claim:

1. An apparatus, comprising:
an open bath immersion tank;
a supply manifold connected to a plurality of direct liquid cooling loops;
a return manifold connected to the direct liquid cooling loops;
a plurality of system boards located within the open bath immersion tank, individual of the system boards comprising:
one or more first integrated circuit components physically and thermally coupled to one of the direct liquid cooling loops; and
one or more second integrated circuit components not physically or thermally coupled to any of the direct liquid cooling loops; and
a heat exchanger located within the open bath immersion tank.

2. The apparatus of claim 1, wherein individual of the direct liquid cooling loops comprise one or more cold plates and for individual of the system boards, the first integrated circuit components are thermally coupled to the cold plates of one of the direct liquid cooling loops.

3. The apparatus of claim 1, wherein the open bath immersion tank is at least partially filled with an immersion fluid and the one or more first integrated circuit components and the one or more second integrated circuit components of individual of the system boards are immersed in the immersion fluid.

4. The apparatus of claim 1, further comprising a single pump located within the open bath immersion tank.

5. The apparatus of claim 1, wherein the direct liquid cooling loops are connected to the supply manifold and the return manifold via quick disconnect fittings.

6. The apparatus of claim 1, further comprising an additional system board located within the open bath immersion tank, the additional system board comprising a third plurality of integrated circuit components comprising all integrated circuit components attached to the additional system board, wherein none of the third plurality of integrated circuit components are thermally or physically coupled to any of the direct liquid cooling loops.

7. A system comprising:
an immersion tank;
a supply manifold connected to a plurality of direct liquid cooling loops;
a return manifold connected to the plurality of direct liquid cooling loops;
a plurality of system boards located within the immersion tank, individual of the system boards comprising:
one or more first integrated circuit components physically and thermally coupled to one of the direct liquid cooling loops; and
one or more second integrated circuit components not physically and thermally coupled to any of the direct liquid cooling loops;
a heat exchanger located within the immersion tank; and
a cooling distribution unit fluidly coupled to the supply manifold to provide a working fluid to the direct liquid cooling loops.

8. The system of claim 7, wherein individual of the direct liquid cooling loops comprise one or more cold plates and for individual of the system boards, the first integrated circuit components are thermally coupled to the cold plates of one of the direct liquid cooling loops.

9. The system of claim 7, wherein the immersion tank is an open bath immersion tank.

10. The system of claim 7, wherein the working fluid provided to the direct liquid cooling loops is a first working fluid and the cooling distribution unit is fluidly coupled to the heat exchanger to provide a second working fluid to the heat exchanger.

11. The system of claim 7, wherein the working fluid provided to the direct liquid cooling loops is a first working fluid and wherein the heat exchanger receives a second working fluid from a source other than the cooling distribution unit.

12. The system of claim 7, wherein the working fluid is a single-phase working fluid.

13. The system of claim 7, wherein the working fluid is a two-phase working fluid.

14. The system of claim 7, wherein the immersion tank is at least partially filled with an immersion fluid.

15. The system of claim 14, wherein the one or more first integrated circuit components, the one or more second integrated circuit components, and the heat exchanger are immersed in the immersion fluid.

16. The system of claim 14, wherein the immersion fluid is a single-phase immersion fluid.

17. The system of claim 14, wherein the immersion fluid is non-flammable and has a GWP (global warming potential) of less than 1.

18. The system of claim 14, wherein:
the immersion fluid is a two-phase immersion fluid;
the immersion tank is a closed bath immersion tank;
the return manifold comprises a condenser to condense immersion fluid vapor; and
the system further comprises an energy reclamation unit fluidly coupled to the return manifold and the cooling distribution unit to receive the working fluid from the return manifold to provide the working fluid to the cooling distribution unit, the energy reclamation unit to convert thermal energy of the working fluid into electricity.

19. The system of claim 7, wherein the cooling distribution unit is to further adjust a flow rate of the working fluid to the supply manifold based on an amount of power consumed by the first integrated circuit components of at least one of the system boards.

20. The system of claim 7, further comprising:
a gas inlet to provide a pressurized inert gas to the closed bath immersion tank;
a gas pressure sensor located in the closed bath immersion tank to provide gas pressure sensor data indicating a gas pressure above the immersion fluid; and
a gas pressure controller to control a flow of the pressurized inert gas to the closed bath immersion tank to maintain a target gas pressure above the immersion fluid.

21. The system of claim 7, wherein the cooling distribution unit is fluidly connected to one or more additional supply manifolds to provide the working fluid to one or more pluralities of direct liquid cooling loops physically and thermally coupled to integrated circuit component attached to system boards located within one or more additional immersion tanks.

22. A method comprising:
providing a first working fluid to a supply manifold;
cooling the first working fluid received from a return manifold, the supply manifold and the return manifold connected to a plurality of direct liquid cooling loops physically and thermally coupled to a first plurality of integrated circuit components attached to a plurality of system boards located within an immersion tank at least partially filled with an immersion fluid, the first plurality of integrated circuit components immersed in the immersion fluid, the first working fluid heated by the first plurality of integrated circuit components;
providing a second working fluid to a heat exchanger located within the immersion tank and immersed in the immersion fluid; and
cooling the second working fluid received from the heat exchanger, a second plurality of integrated circuit components located within the immersion tank and immersed within the immersion fluid, the second plurality of integrated circuit components not physically and thermally coupled to the plurality of direct liquid cooling loops.

23. The method of claim 22, further comprising adjusting a flow rate of the first working fluid to the supply manifold based on an amount of power consumed by the first plurality of integrated circuit components of at least one of the system boards.

24. The method of claim 22, wherein the immersion tank is a closed bath immersion tank, the method further comprising adjusting a flow of pressurized inert gas into the closed bath immersion tank based on gas pressure sensor data provided by a gas pressure sensor indicating a gas pressure above the immersion fluid.
